(19) United States
(12) Patent Application Publication
(10) Pub. No.: US 2013/0152562 A1
(43) Pub. Date: Jun. 20, 2013

(54) THERMOELECTRIC GENERATOR OF VEHICLE

(71) Applicants: Ho-Chan An, Hwasung-shi (KR); Jong-Ho Seon, Incheon-shi (KR)

(72) Inventors: Ho-Chan An, Hwasung-shi (KR); Jong-Ho Seon, Incheon-shi (KR)

(73) Assignee: Hyundai Motor Company, Seoul (KR)

(21) Appl. No.: 13/624,749

(22) Filed: Sep. 21, 2012

(30) Foreign Application Priority Data
Dec. 15, 2011 (KR) 10-2011-0135138

(51) Int. Cl. F01N 5/02; H01L 35/30

(52) U.S. Cl. 60/320; 136/208; 136/210

(57) ABSTRACT

A thermoelectric generator may include a high temperature member having an exhaust pipe, and a ring-shaped first heat transfer plate equipped with a first flange installed on an external wall of the exhaust pipe and formed along a longitudinal direction of the exhaust pipe, a low temperature member having a first coolant pipe enclosing an external wall of the exhaust pipe, and a ring-shaped second heat transfer plate installed inside the first coolant pipe, and on which a second flange extends along a longitudinal direction of the first coolant pipe, and ring-shaped thermoelectric modules, which may be formed by joining a P-shaped semiconductor and an N-shaped semiconductor.

### CROSS-REFERENCE TO RELATED APPLICATION

The present application claims priority to Korean Patent Application No. 10-20110135138, filed on Dec. 15, 2011, the entire contents of which is incorporated herein for all purposes by this reference.

### BACKGROUND OF THE INVENTION

1. Field of the Invention

The present invention relates to a thermoelectric generator of vehicle, and more particularly, to a thermoelectric generator of vehicle, which uses the heat of the exhaust gas of an automobile to generate electricity.

2. Description of Related Art

A thermoelectric element is an element, which uses a thermoelectric phenomenon, in which thermal energy is converted to electric energy by converting the temperature gap between the two ends of an element into electricity, or in which electric energy is converted to thermal energy by having electricity run through an element and by causing the temperature gap in the two ends. Such thermoelectric element is used in a small scale cooling, heating or generating device.

When a thermoelectric element is used in a small scale generating device, it is called a thermoelectric generation device or a thermoelectric generator. This device is mainly used in a power supply unit of a wireless communication device, of a spaceship and of a nuclear-powered submarine as well as in a thermoelectric generator installed in an exhaust system of a vehicle.

FIG. 1 is a cross-sectional view illustrating a thermoelectric generator of a vehicle.

As illustrated, a thermoelectric generator installed in an exhaust system of a vehicle 10 comprises; a hexagonal exhaust heat recovering device 40, which high-temperature exhaust gas passes through; a cooling device 30, which is installed outside of the exhaust heat recovering device 40 and inside of which coolant passes through; and the multitude of thermoelectric modules 20, which are in contact with the exterior of the exhaust heat recovering device 40 and with the interior of the cooling device 30 to generate electricity using the temperature gap between the two ends.

Inside the exhaust heat recovering device 40, high-temperature exhaust gas runs and it conveys thermal energy to the thermoelectric modules 20. Inside the cooling device 30 is formed a cooling pipe, which increases the temperature gap between the interior of the thermoelectric modules 20 in contact with the exhaust heat recovering device 40 and the exterior of the thermoelectric modules 20 in contact with the cooling device 30. As the temperature gap between the interior and the exterior of the thermoelectric module increases 20, the efficiency of the thermoelectric generator installed in the exhaust system of a vehicle increases.

In order to generate lots of electricity in a thermoelectric generator, i.e. to increase the thermoelectric generation efficiency, thermal energy of the exhaust gas must be conveyed to the thermoelectric modules efficiently. However, in the traditional thermoelectric generator of a vehicle, thermal energy of the exhaust gas is not conveyed to the high temperature member sufficiently, so the recovery rate of the thermal energy of the exhaust gas drops and hence, the thermoelectric efficiency of a thermoelectric generator drops.

Also, in the traditional thermoelectric generator of a vehicle, although a cooling device 30 occupies a great area, the heat-exchange area is small, and therefore, the heat conveyance rate is low compared to the size, and the efficiency of thermoelectric generation is low.

The information disclosed in this Background of the Invention section is only for enhancement of understanding of the general background of the invention and should not be taken as an acknowledgement or any form of suggestion that this information forms the prior art already known to a person skilled in the art

### BRIEF SUMMARY

Various aspects of the present invention are directed to providing a small thermoelectric generator of a vehicle, with the improved efficiency of the thermoelectric generation.

In an aspect of the present invention, a thermoelectric generator of a vehicle may include a high temperature member having an exhaust pipe, through which a high temperature exhaust gas passes, wherein the exhaust pipe is heated by a heat exchange process with the exhaust gas, a ring-shaped first heat transfer plate equipped with a first flange installed on an external wall of the exhaust pipe and formed along a longitudinal direction of the exhaust pipe, a low temperature member having a first coolant pipe enclosing an external wall of the exhaust pipe with a predetermined space therebetween, and inside of which a coolant runs, and a ring-shaped second heat transfer plate installed inside the first coolant pipe, and on which a second flange extends along a longitudinal direction of the first coolant pipe, and ring-shaped thermoelectric modules, which are formed by joining a P-shaped semiconductor and an N-shaped semiconductor, and one side of each of which is in contact with the first heat transfer plate and the other side of each of which is in contact with the second heat transfer plate so as to generate electricity using a thermoelectric phenomenon caused by a temperature gap between the two sides.

The generator may further include a bypass pipe, which is installed inside the exhaust pipe with a predetermined gap and through which the exhaust gas bypasses, a bypass valve mounted on an end of the bypass pipe to open and close the bypass pipe according to the exhaust gas, an elastic member, which supports the bypass valve elastically against the end of the bypass pipe, and a heat transfer mesh installed between the exhaust pipe and the bypass pipe to convey thermal energy from the exhaust gas to the exhaust pipe.

The first coolant pipe may further include a coolant inlet formed on a lower portion of the first coolant pipe, a coolant outlet, which is formed on a upper portion of the first coolant pipe in the diagonal direction of the coolant inlet and through which the coolant flows out, and a plurality of ring-shaped baffles, which is installed inside the first coolant pipe and forms coolant routes in two opposite directions, wherein the plurality of baffles may have one end opened and the opened side is arranged in a fixed angle.

The generator may further include a second coolant pipe that is disposed inside the first coolant pipe with a predetermined gap and contacts with the second flange of the ring-shaped second heat transfer plate, wherein the coolant flows between the first coolant pipe and the second coolant pipe.

The generator may further include the first coolant pipe may further include a coolant inlet formed on a lower portion of the first coolant pipe, a coolant outlet, which is formed on a upper portion of the first coolant pipe in the diagonal direction of the coolant inlet and through which the coolant flows out, and a plurality of ring-shaped baffles, which is installed between the first coolant pipe and the second coolant pipe and forms coolant routes in two opposite directions, wherein the plurality of baffles may have one end opened and the opened side is arranged in a fixed angle.

In accordance with a thermoelectric generator of the present invention, a structure of a heat conduction plate is simplified, and therefore, the manufacture cost of a thermoelectric generator is reduced and the productivity increased.

Also, the size of a thermoelectric generator is shrunken so as to not only make it easy to install it in a vehicle but also to increase the thermoelectric efficiency since the area of thermoelectric modules is increased for a same-length thermoelectric generator.

Furthermore, by using the generated electricity in the vehicle's small-size electric devices and in charging the battery, the engine load can be lowered and the fuel efficiency be improved.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a cross sectional view of a traditional thermoelectric generator of a vehicle.

FIG. 2 is a longitudinal sectional view of a thermoelectric generator of a vehicle according to an exemplary embodiment of the present invention.

FIG. 3 is a magnified sectional view of the ‘A’ portion of FIG. 2.

FIG. 4 is an exploded perspective view of first heat exchange pins, thermoelectric modules and second heat exchange pins of a thermoelectric generator of a vehicle according to an exemplary embodiment of the present invention.

FIG. 5 is a cross-sectional view of FIG. 2 cut through the line A-A′.

FIG. 6 is a perspective view of baffles of a thermoelectric generator according to an exemplary embodiment of the present invention.

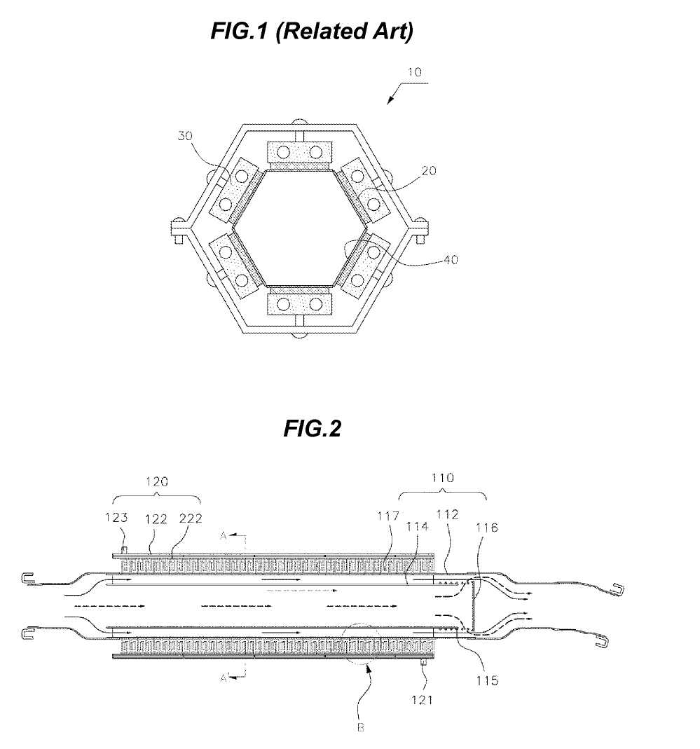

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Reference will now be made in detail to various embodiments of the present invention, examples of which are illustrated in the accompanying drawings and described below. While the invention will be described in conjunction with exemplary embodiments, it will be understood that the present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

Hereafter, with reference to the attached drawings, the exemplary embodiment of the present invention will be described in detail. Before proceeding, it should be noted that the terminologies and words used on this specification and in the claims are not to be interpreted solely as the general or dictionary meanings, and they should be interpreted as the meanings and the concept which correspond with the technological ideas of the present invention based on the principle that the inventor can properly define the concept of the terminologies in order to explain his own invention in the best possible way. Therefore, the compositions described in the exemplary embodiments and the drawings of this specification are merely the most preferred types of embodiment and they do not represent the entire technological ideas of the present invention, and thus, it should be understood that there can be a variety of equivalents and alterations, which can replace these embodiments at the time of filing this application.

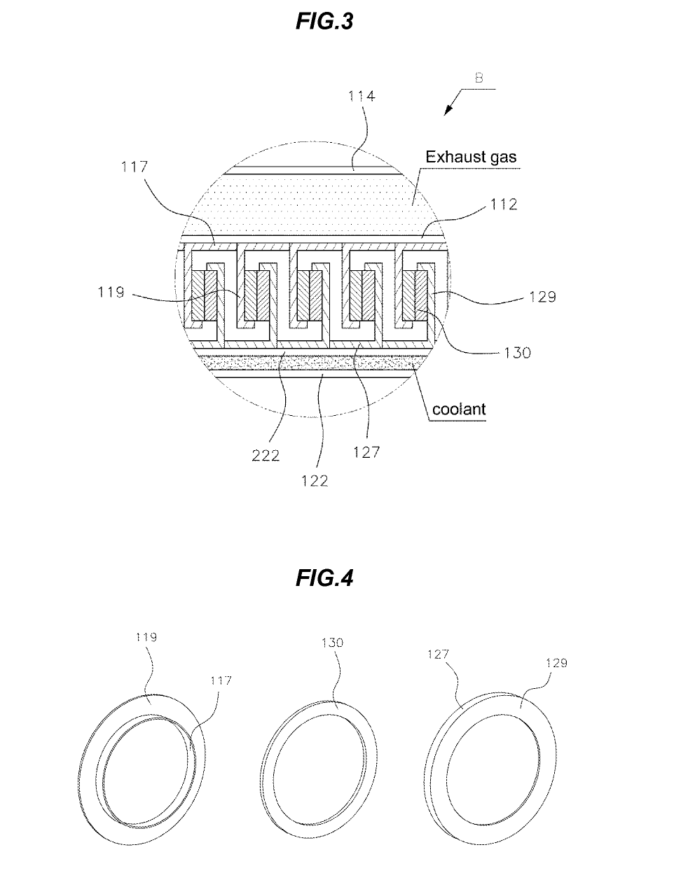

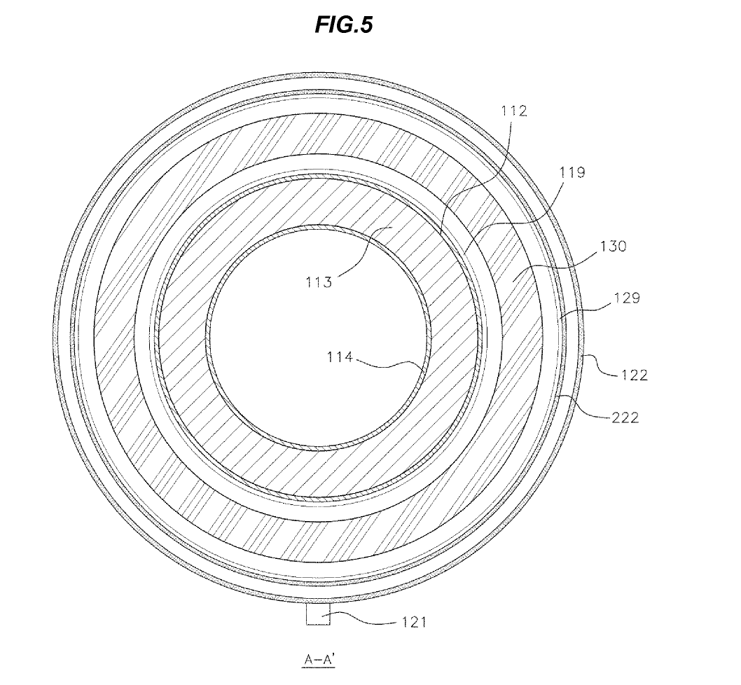

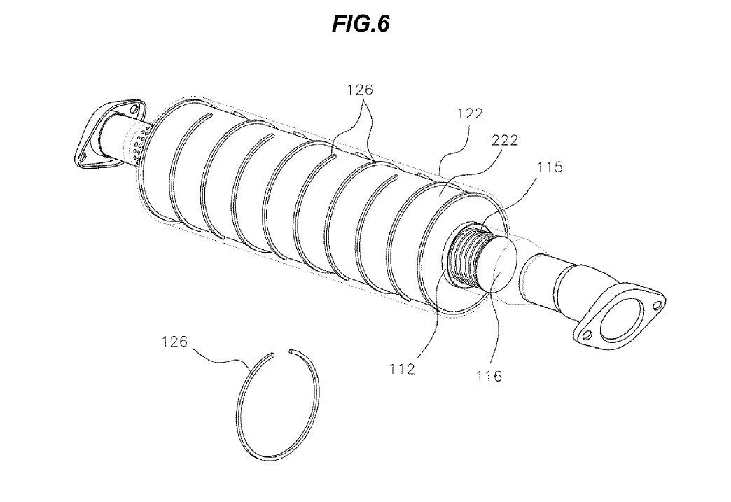

FIG. 2 is a longitudinal sectional view of a thermoelectric generator of a vehicle according to an exemplary embodiment of the present invention. FIG. 3 is a magnified sectional view of the ‘A’ portion of FIG. 2. FIG. 4 is an exploded perspective view of first heat exchange pins, thermoelectric modules and second heat exchange pins of a thermoelectric generator of a vehicle according to an exemplary embodiment of the present invention. FIG. 5 is a cross-sectional view of FIG. 2 cut through the line A-A′. FIG. 6 is a perspective view of baffles of a thermoelectric generator according to an exemplary embodiment of the present invention.

As illustrated, a thermoelectric generator of a vehicle according to an exemplary embodiment of the present invention includes a high temperature member 110, which exchanges heat with the high-temperature exhaust gas emitted from the engine and becomes heated, a low temperature member 120, which is installed outside the high temperature member 110 and through which coolant that is circulated by the cooling system flows, and thermoelectric modules 130, which lie between the high temperature member 110 and the low temperature member 120 and use the thermoelectric phenomenon caused by the temperature gap between the high temperature member 110 and the low temperature member 120 to generate electricity.

The high temperature member 110 further includes an exhaust pipe 112, which becomes heated as the exhaust gas passes through it, a ring-shaped first heat transfer plate 119 installed on the external wall of the exhaust pipe, a first flange 117, which extends from the internal wall of the heat transfer plate 119 in the longitudinal direction of the exhaust pipe to be in contact with the thermoelectric modules 130.

The exhaust pipe 112 has a shape of a hollow cylinder and is heated by the high-temperature exhaust gas passing through it. The exhaust pipe 112 heated in the above method heats up the first heat transfer plate 119 installed on its external wall, and one side of the thermoelectric modules 130 is heated by the first heat transfer plate 119.

Inside the exhaust pipe 112 is installed a bypass pipe 114, which the exhaust gas bypasses. On the end of the bypass pipe 114 is installed a bypass valve 116, which opens and closes the end of the bypass pipe 114 depending on the engine load so that the exhaust gas can bypasses it. The bypass valve 116 is supported elastically against the bypass pipe 114 by a spring 115.

Between the external wall of the bypass pipe 114 and the internal wall of the exhaust pipe 112 lies a heat exchange mesh 113. The heat exchange mesh 113 exchanges heat with the high-temperature exhaust gas, absorbs thermal energy of the exhaust gas and conveys it to the exhaust pipe 112. In other words, thermal energy is efficiently conveyed to the exhaust pipe 112 by the heat exchange mesh 113.

When a vehicle runs at a high speed, i.e., when the engine load is increased, the exhaust pipe 112 can be overheated. In order to prevent this, the bypass valve 116 is opened when the engine is overloaded and most of the high-temperature exhaust gas is emitted through the bypass pipe 114, and hence, the amount of the exhaust gas that runs between the bypass pipe 114 and the exhaust pipe 112 is controlled.

Outside of the high temperature member 110, in other words, outside of the exhaust pipe 112, is installed the low temperature member 120. The low temperature member 120 has a shape of a hollow cylinder and includes a coolant pipe 122 and another coolant pipe 222, such that coolant flow route is formed therebetween for the coolant to flow through. The coolant pipe 122 is equipped with a coolant inlet 121, which is formed on the lower flow route of the exhaust pipe 112, i.e. outside of the one end of the coolant pipe 122 so that the coolant flows into the flow route, and a coolant outlet 123, which is formed on the upper flow route of the exhaust pipe 112, in other words, in a diagonal direction of the coolant inlet 121 from the center line of the coolant pipe 112. As illustrated in FIG. 2, the coolant flows inside the coolant pipe 122 through the coolant inlet 121, flows along the coolant flow route, flows out through the coolant outlet 123 formed in a diagonal direction and is collected at the cooling system not illustrated of the engine.

The low temperature member 120 includes a second heat transfer plate 129 installed on the internal wall of the coolant pipe 222. The second heat transfer plate 129 touches the internal wall of the coolant pipe 222 through a second flange 127, which extends in the longitudinal direction of the coolant pipe 222, on its external wall. On the internal wall of the second heat transfer plate 129 is attached the thermoelectric modules 130.

The low temperature member 120 includes a multitude of baffles 126 installed between the coolant pipe 122 and the coolant pipe 222 to form the flow route of the coolant therebetween. As illustrated in FIG. 6, each baffle 126 has a shape of an opened ring. The baffles 126 are installed in a way that the opened portions of the baffles 126 form a fixed angle with one another. In other words, one opened portion of a coolant baffle 126 is set to form a fixed angle, preferably 90 degrees, with another opened portion of an adjacent coolant baffle.

Since a multitude of coolant baffles is installed this way, coolant flows along a flow route in the opposite direction of the direction of the coolant flowing along an adjacent flow route. The reason for such a set-up is to keep the temperature of a low temperature member constant.

The thermoelectric modules are formed by joining a P-shaped semiconductor and an N-shaped semiconductor, which lie between the first heat transfer plate 119 of the high temperature member 110 and the second heat transfer plate 129 of the low temperature member 120. The thermoelectric modules 130 lie between the first flange 117 and the second flange 127, and its one side is heated by the first heat transfer plate 119 and its other side is cooled by the second heat transfer plate 129.

Hence, a temperature gap occurs between the two sides of the thermoelectric modules 130, and electricity is generated inside the thermoelectric modules 130 by this temperature gap. The generated electricity is used to charge the vehicle's battery not illustrated, which is electrically connected to the thermoelectric modules 130.

The above-described first heat transfer plate 119, thermoelectric modules 130 and second heat transfer plate 129 form one thermoelectric module, and a multitude of thermoelectric modules is installed between the cooling pipe 222 and the cooling pipe 122. At this time, the multitude of thermoelectric modules 130 is electrically connected to each other so as to generate lots of electricity.

Now, the application of a thermoelectric generator of a vehicle according to an exemplary embodiment of the present invention described above will be explained.

When the engine is run, exhaust gas is emitted from the engine and flows into the exhaust pipe 112, and this is when the bypass valve 116 closes the bypass pipe 114. Meanwhile, coolant circulated by a cooling system of the engine flows into the coolant inlet 121.

The exhaust gas flows inside the exhaust pipe 112 exchanges heat with the exhaust pipe 112, and the exhaust pipe 112 becomes heated. The first heat transfer plate 119 installed on the external wall of the exhaust pipe 112 is heated by the heated exhaust pipe 112, and thermal energy of the exhaust gas is conveyed to one side of the thermoelectric modules 130 by the heated first heat transfer plate 119.

Also, the coolant that flows into the coolant inlet 121 flows into the flow routes formed by the baffles 126 adjacent to the inside of the coolant pipe 122, and the flow routes are formed in a way that the coolant alternates in the direction it flows. The flowing coolant cools down the second heat transfer plate 129, and the other side of the thermoelectric modules 130 in contact with the second heat transfer plate 129 is cooled.

Thus, a temperature gap occurs between the two sides of the thermoelectric modules 130. The temperature gap generates electricity inside the multitude of thermoelectric modules 130.

When the speed of a vehicle increases, i.e. when the engine load increases, the bypass valve 116 beats the elasticity of the spring 115 and opens the bypass pipe 114. As the bypass pipe 114 is opened, most of the exhaust gas is emitted through the bypass pipe 114 and the rest flows between the bypass pipe 114 and the exhaust pipe 112. The heat exchange mesh 113 lying between the bypass pipe 114 and the exhaust pipe 112 exchanges heat with the exhaust gas and heats up the exhaust pipe 112, and the remaining process thereafter is identical to the process when the bypass valve 116 is closed, so further explanation will be omitted.

Since a multitude of thermoelectric modules can be used, a large quantity of electricity can be generated, and using the electricity generated, the vehicle's battery can be charged and the fuel efficiency of the vehicle can be increased.

For convenience in explanation and accurate definition in the appended claims, the terms “upper”, “lower”, “inner” and “outer” are used to describe features of the exemplary embodiments with reference to the positions of such features as displayed in the figures.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A thermoelectric generator of a vehicle comprising;
a high temperature member having:
an exhaust pipe, through which a high temperature exhaust gas passes, wherein the exhaust pipe is heated by a heat exchange process with the exhaust gas;
a ring-shaped first heat transfer plate equipped with a first flange installed on an external wall of the exhaust pipe and formed along a longitudinal direction of the exhaust pipe;
a low temperature member having:
a first coolant pipe enclosing an external wall of the exhaust pipe with a predetermined space therebetween, and inside of which a coolant runs; and
a ring-shaped second heat transfer plate installed inside the first coolant pipe, and on which a second flange extends along a longitudinal direction of the first coolant pipe; and
ring-shaped thermoelectric modules, which are formed by joining a P-shaped semiconductor and an N-shaped semiconductor, and one side of each of which is in contact with the first heat transfer plate and the other side of each of which is in contact with the second heat transfer plate so as to generate electricity using a thermoelectric phenomenon caused by a temperature gap between the two sides.

2. The generator according to claim 1, further including:
a bypass pipe, which is installed inside the exhaust pipe with a predetermined gap and through which the exhaust gas bypasses;
a bypass valve mounted on an end of the bypass pipe to open and close the bypass pipe according to the exhaust gas;
an elastic member, which supports the bypass valve elastically against the end of the bypass pipe; and
a heat transfer mesh installed between the exhaust pipe and the bypass pipe to convey thermal energy from the exhaust gas to the exhaust pipe.

3. The generator according to claim 1, wherein
the first coolant pipe further includes a coolant inlet formed on a lower portion of the first coolant pipe;
a coolant outlet, which is formed on a upper portion of the first coolant pipe in the diagonal direction of the coolant inlet and through which the coolant flows out; and
a plurality of ring-shaped baffles, which is installed inside the first coolant pipe and forms coolant routes in two opposite directions,
wherein the plurality of baffles has one end opened and the opened side is arranged in a fixed angle.

4. The generator according to claim 1, further including a second coolant pipe that is disposed inside the first coolant pipe with a predetermined gap and contacts with the second flange of the ring-shaped second heat transfer plate, wherein the coolant flows between the first coolant pipe and the second coolant pipe.

5. The generator according to claim 4, wherein
the first coolant pipe further includes a coolant inlet formed on a lower portion of the first coolant pipe;
a coolant outlet, which is formed on a upper portion of the first coolant pipe in the diagonal direction of the coolant inlet and through which the coolant flows out; and
a plurality of ring-shaped baffles, which is installed between the first coolant pipe and the second coolant pipe and forms coolant routes in two opposite directions,
wherein the plurality of baffles has one end opened and the opened side is arranged in a fixed angle.
